(19) United States
(12) Patent Application Publication
(10) Pub. No.: US 2012/0063112 A1
(43) Pub. Date: Mar. 15, 2012

(54) ELECTRONIC DEVICE

(75) Inventors: TING-TING ZHAO, Shenzhen City (CN); WEI LIU, Shenzhen City (CN); HE-LI WANG, Shenzhen City (CN); CHIN-SUNG YANG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/095,948

(22) Filed: Apr. 28, 2011

(30) Foreign Application Priority Data
Sep. 15, 2010 (CN) 201010282157.X

(51) Int. Cl. H05K 7/02

(52) U.S. Cl. 361/807

(57) ABSTRACT

An electronic device includes a main body, a hinge, a display, and a protective structure. A recessed portion is defined in an edge area of the main body. The hinge includes a shaft passing through the recessed portion with a part of an outer surface exposed in the recessed portion. The display is connected to the main body with the hinge and is capable of rotating relative to the main body with the shaft. The protective structure is detachably mounted to the main body and partly received in the recessed portion for engaging with the main body to completely receive the outer surface of the shaft.

### BACKGROUND

1. Technical Field

The present disclosure relates to electronic devices, and particularly to an electronic device with a main body and a display pivotably connected to the main body.

2. Description of Related Art

An electronic device, such as an optical disc player, often includes a main body, a display, and a hinge. The hinge pivotably connects the display to the main body so the display can rotate relative to the main body. Generally, the hinge includes a shaft passing through a through hole defined in the main body. For stably connection of the display to the main body, it is preferable that the shaft is large enough to bear the connection stress from the display and the main body. However, on the other hand, the through hole should not be too large because of the limitation of the miniaturization of the main body, which results in the difficulty of mounting the hinge to the main body.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an electronic device according to an embodiment of the present disclosure. The electronic device includes a protective structure and a main body with a cover.

FIG. 2 is a partially exploded cutaway view of the electronic device of FIG. 1 from a reverse direction to FIG. 1.

FIG. 3 is a partial cutaway schematic view of the cover of FIG. 1.

FIG. 4 is a schematic view of the protective structure of FIG. 1.

FIG. 5 is similar to FIG. 4 but from a reverse angle.

### DETAILED DESCRIPTION

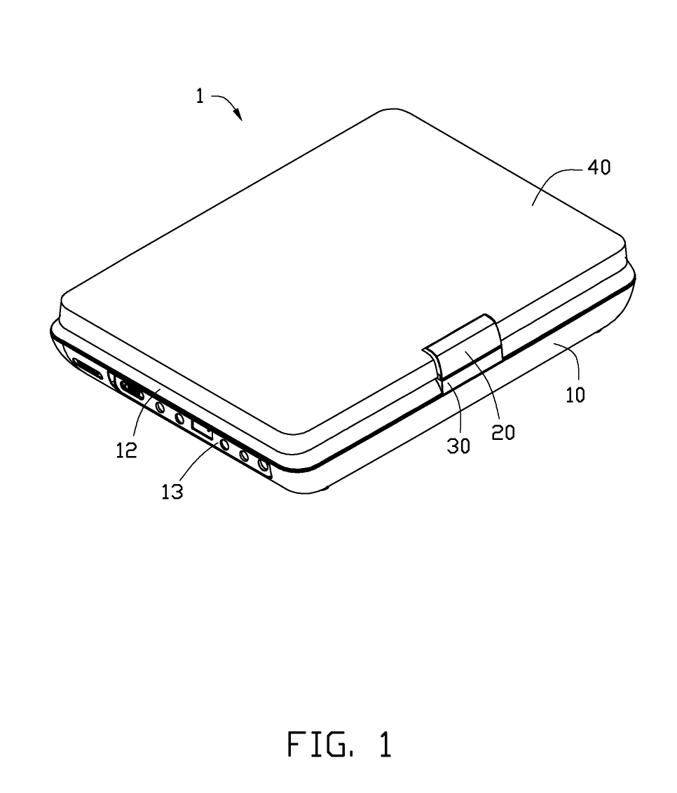

Referring to FIG. 1, an electronic device 1 includes a display 40, a main body 10, a hinge 20, and a protective structure 30. The hinge 20 pivotably connects the display 40 to the main body 10 such that the display 40 can rotate relative to the main body 10. The protective structure 30 is detachably mounted to the main body 10. In an embodiment, the electronic device 1 is an optical disc player. In other embodiments, the electronic device 1 may be other devices such as a notebook computer.

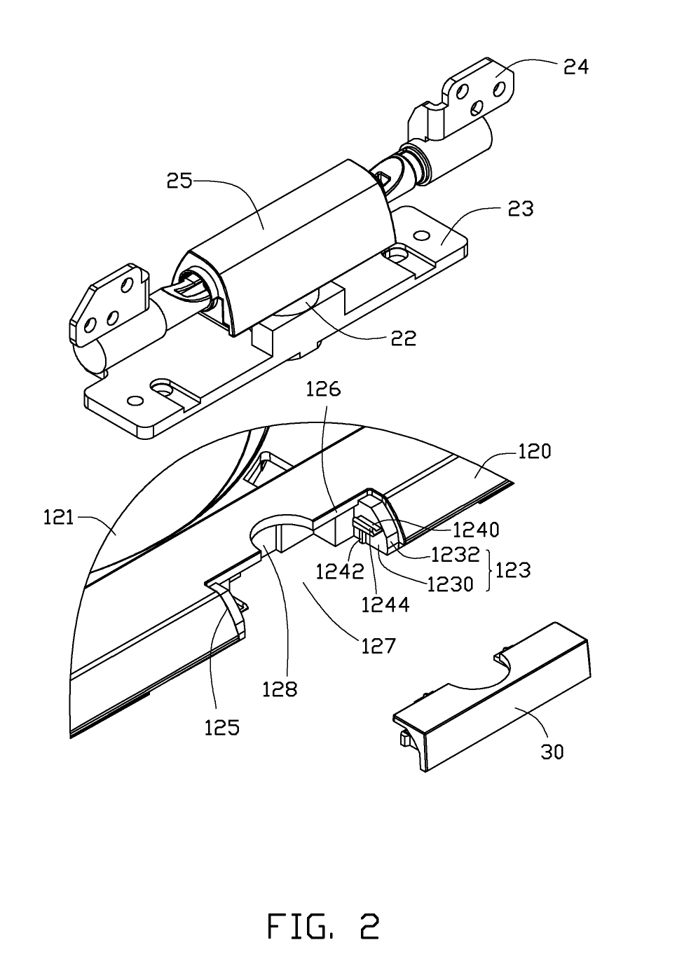

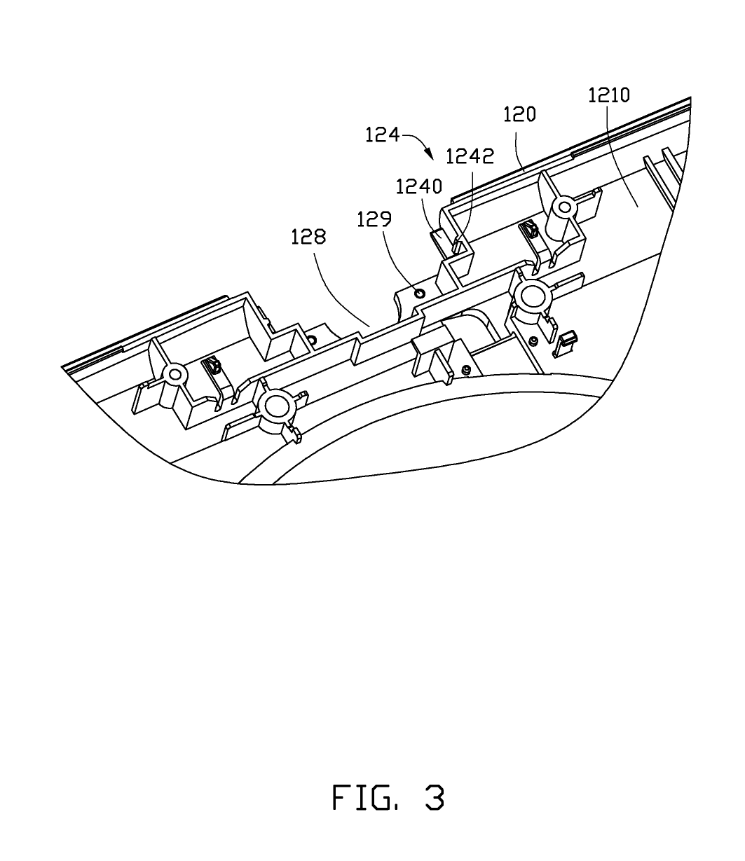

Also referring to FIGS. 2 and 3, the main body 10 includes a cover 12 and a base 13. The cover 12 includes a side plate 120, a bottom plate 121, two connection members 123, and two first clamping members 124. The side plate 120 is connected to the bottom plate 121 to form the cover 12. The side plate 120 is partially cut in the middle portion thereof to form an opening 127, two connection walls 125 at opposite sides of the opening 127, and a bottom wall 126 perpendicularly connected to the two connection walls 125. The bottom wall 126 and the two connection walls 125 surround the opening 127. The bottom wall 126 defines a first slot 128, which extends into the bottom plate 121. The first slot 128 communicates with the opening 127. In the embodiment, the first slot 128 is defined in the middle portion of the bottom wall 126 and is semi-circular shaped. Two notches 129 symmetric about the first slot 128 are defined in the inner surface 1210 of the bottom plate 121.

The connection members 123 are received in the opening 127 and are respectively connected to the connection walls 125. Each connection member 123 includes a connection surface 1230 and a top surface 1232 perpendicularly defined between the connection surface 1230 and the corresponding connection wall 125. The connection surface 1230 is parallel with the corresponding connection wall 125. The top surface 1232 is substantially parallel with the side plate 120 and is below the outer surface of the side plate 120.

The first clamping members 124 are also received in the opening 127, and are respectively fixed to the two connection members 123 and face each other. Each first clamping member 124 includes a first rib 1240 and a second rib 1242 perpendicularly connected to the first rib 1240 disposed on the connection surface 1230. In the embodiment, each first rib 1240 is substantially parallel with the bottom plate 121, while each second rib 1242 is substantially perpendicular to the bottom plate 121. A protrusion 1244 protrudes upwardly from one side of the first rib 1240 away from the corresponding connection wall 123.

The hinge 20 includes a shaft 22, a first hinge member 23, a second hinge member 24, and a covering member 25. The first hinge member 23 is used for connecting the shaft 22 to the base 13. The second hinge member 24 is used for connecting the shaft 22 to the display 40. The covering member 25 is disposed on the hinge member 23 lengthwise along the length of the side plate 120 equal to that of the bottom wall 126.

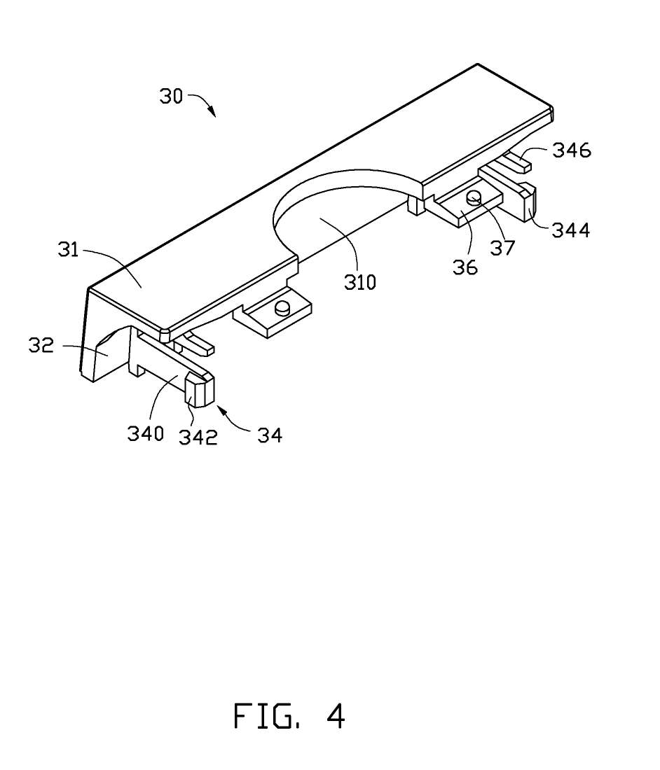

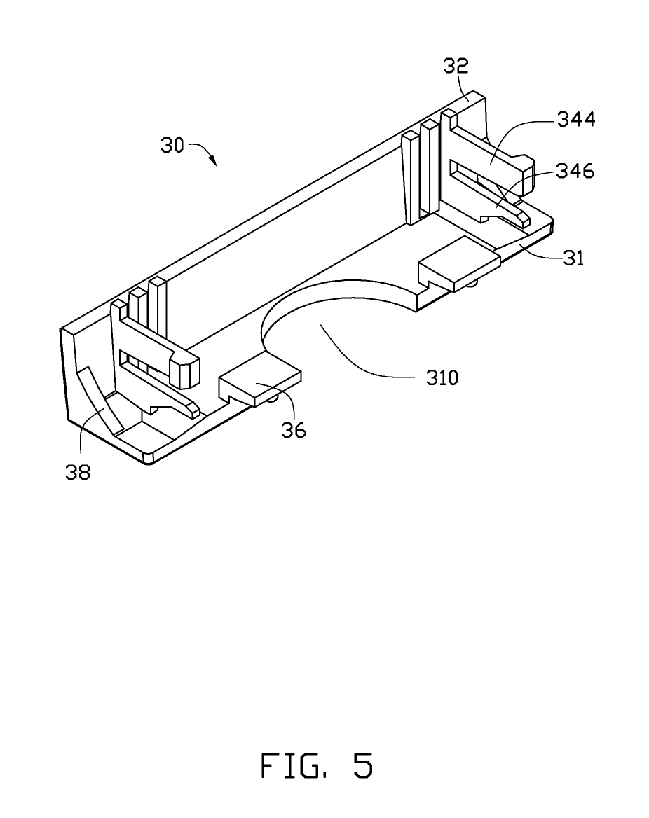

Referring to FIGS. 4 and 5, the protective structure 30 is shaped to fit the opening 127. The protective structure 30 includes a first part 31, a second part 32, two second clamping members 34, and two extending plates 36. The first part 31 is substantially rectangular extending lengthwise along the length of the side plate 120 equal to the bottom wall 126 and the covering member 25. The second part 32 extends perpendicularly from the first part 31. The thickness of both the first part 31 and the second part 32 are equal to the distance between the top surface 1232 and the outer surface of the side plate 120. A second slot 310 is defined in the middle portion of the first part 31. The second slot 310 is semi-circular shaped and corresponds to the first slot 128.

The second clamping members 34 perpendicularly protrude from two opposite sides of the second part 32 respectively. Each second clamping member 34 includes a clamping portion 340 protruding from the second part 32 and a hook 342. Each clamping portion 340 includes a first post 344 and a second post 346 spaced from each other. The hook 342 is disposed on an end of the corresponding first post 344 away from the second part 32.

The extending plates 36 perpendicularly extend from an edge of the first part 31 away from the second part 32. The extending plates 36 are parallel with the first part 31 and symmetric about the second slot 310. Two blocks 37 respectively project from one side of the extending plates 36 away from the second part. Two abutting members 38 are disposed between the first part 31 and the second part 32, and shaped to fit the top surface 1232.

In assembly, the first hinge member 23 is fixed on an inner surface of the base 130 at first. Then the cover 12 is mounted to the base 130 with the side plate 120 approaching the hinge 20 along a first direction substantially perpendicular to the side plate 120, and with the first slot 128 corresponding to the shaft 22 and the covering member 25. After the cover 12 is mounted to the base 130, the hinge member 24 passes through the cover 12 via the opening 127 to be exposed above the cover 12. The shaft 22 passes through the first slot 128, with a half of the side surface received in the first slot 128 and the other half exposed in the opening 127. The display 40 then can be fixed to the main body 10 by connecting to the second hinge member 24.

After that, the protective structure 30 is mounted to the cover 12. The protective structure 30 is attached on the cover 12 and corresponds to the opening 127 at first, with the first clamping members 124 corresponding to the second clamping members 34 and the edge from which the extending plates 36 extend contacting the bottom wall 123. In this configuration, each first rib 1240 passes through the space defined by the two posts of the corresponding clamping portion 340. Each hook 342 hooks on a side of the corresponding second rib 1242 adjacent to the bottom wall 123. Therefore, the protective cover 30 is fixed to the main body 10 and cannot move along the first direction and a second direction substantially parallel with the side plate 120. The abutting members 38 abut the top surfaces 1232, thereby preventing the protective cover 30 from moving downwards along the second direction. The second slot 310 is conformed to the first slot 128 to define a through hole through which the shaft 22 passes. That is, with the conformation between the first slot 128 and the second slot 310, the protective structure 30 encloses the other half of the outer side surface of the shaft 22 exposed in the opening 127. At the same time, the extending plates 36 contact the inner surface of the bottom plate 120 and each block 37 is received in the corresponding notch 129, thereby preventing the protective structure 30 from moving away from the cover 12 along the first direction. Moreover, in a situation where the space between the first post 344 and the second post 346 is larger than the thickness of the first rib 1240, the protrusions 1244 can restrict the clamping portions 340 from moving away from the connection walls 123 along a third direction perpendicular to the first and the second direction. Thus, the protective structure 30 is steadily fixed to the cover 12 and is received in the opening 127.

After the protective structure 30 is mounted on the main body 10, the first part 31 is substantially coplanar with the bottom plate 120 to be a part of the bottom plate 120, and the part 32 is substantially coplanar with the side plate 120 to be a part of the side plate 120.

The first clamping members 124 and the second clamping member 34s are not limited to this embodiment. In an alternative embodiment, the second clamping members 34 may be disposed on the cover 12 and the first clamping members 124 may be disposed on the protective structure 30. In addition, in other embodiments, the blocks 37 may protrude out from the inner surface of the cover 12 while the notches 129 may be defined in the extending plates 36.

With engagement between the first clamping members 124 and the second clamping members 34, and the conformation between the notches 129 and the blocks 37, the protective structure 30 can be mounted to the main body 10 steadily and can be removed from the main body 10 easily. When the protective structure 30 is mounted in the opening 127, the protective structure 30 can engage with the main body 10 to enclose the outer side surface of the shaft 22, which makes the shaft 22 avoid being damaged easily by the environment. Additionally, the first part 31 is coplanar with the bottom plate 121 and the second part 32 is substantially coplanar with the side plate 120, which transfigures the main body 10.

It is to be understood, however, that even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a main body with a recessed portion defined in an edge area thereof;
a hinge comprising a shaft passing through the main body via the recessed portion;
a display connected to the main body by the hinge and capable of rotating relative to the main body by the shaft;
a protective structure detachably mounted in the recessed portion and engaging with the main body to enclose an outer side surface of the shaft.

2. The electronic device as claimed in claim 1, wherein the main body further comprises at least one first clamping member, the protective structure comprises at least one second clamping member, the at least one first clamping member engages with the at least one second clamping member for preventing the protective structure from moving away from the main body.

3. The electronic device as claimed in claim 2, wherein the main body comprises a side plate partly defining the edge area, the recessed portion comprises an opening defined in the side plate and shaped to conformed to the protective structure, the main body comprises two first clamping members respectively locating at two sides of the opening and facing each other, the protective structure comprises two second clamping members protruding at two opposite sides thereof for respectively engaging with the first clamping members.

4. The electronic device as claimed in claim 3, wherein each first clamping member comprises a first rib, each second clamping member comprises a clamping portion, the clamping portion comprises two spaced apart posts for clamping the first rib to prevent the protective structure from moving along a first direction substantially parallel with the side plate.

5. The electronic device as claimed in claim 4, wherein each first clamping member further comprises a second rib adjacent to the first rib, and each second clamping member further comprises a hook protruding from one post of the clamping portion, each hook abuts the second rib for preventing the protective structure from moving away from the main body along a second direction substantially perpendicular to the side plate.

6. The electronic device as claimed in claim 5, wherein each first clamping member further comprises a protrusion protruding from one side of the first rib which is opposite to the corresponding side of the opening for restricting the corresponding clamping portion from moving along a third direction perpendicular to the first direction and the second direction.

7. The electronic device as claimed in claim 6, wherein the second rib is perpendicular to the corresponding first rib with one end thereof connected to the first rib.

8. The electronic device as claimed in claim 6, wherein the main body comprises two connection members respectively locating at the two sides of the opening, each connection member comprises a connection surface perpendicular to the side plate, each first clamping member is connected to the corresponding connection surface.

9. The electronic device as claimed in claim 8, wherein each connection member further comprises a top surface defined between the connection surface and the side plate, the top surface is parallel with the side plate and below an outer surface of the side plate, the protective structure comprises two abutting members respectively abutting the top surfaces for preventing the protective structure from moving along the first direction.

10. The electronic device as claimed in claim 4, wherein the main body comprises a bottom plate substantially perpendicularly connected to the side plate, the recessed portion further comprises a first slot defined in the bottom plate and communicates with the opening, the shaft passes through the first slot with a part of the outer side surface thereof exposed in the opening.

11. The electronic device as claimed in claim 10, wherein the bottom plate defines at least one notch adjacent to the first slot, and the protective structure comprises at least one block received in the at least one notch for preventing the protective structure from moving away from the main body along a second direction substantially perpendicular to the side plate.

12. The electronic device as claimed in claim 10, wherein the protective structure defines a second slot, the protective structure engages with the main body to enclose the outer side surface of the shaft for the conformation between the first slot and the second slot.

13. The electronic device as claimed in claim 12, wherein the protective structure comprises a first part coplanar with the bottom plate and a second part substantially coplanar with the side plate, the second slot is defined in the first part, and the second clamping members protrude from two opposite sides of the second part.

14. The electronic device as claimed in claim 13, wherein both the first slot and the second slot are semi-circular shaped.

15. An electronic device, comprising:
a main body;
a rotating member;
a hinge rotatably connecting the rotating member to the main body, the hinge comprising a shaft;
a detachable structure detachedly connected to the main body to define a through hole for passing the shaft through.

16. The electronic device as claimed in claim 15, wherein the main body comprise a side plate defining an opening and a bottom plate connected to the side plate, the detachable structure is shaped to fit the opening, a first slot is defined in the bottom plate and communicates with the opening, the detachable structure defines a second slot shaped to conformed to the first slot to define the through hole.

17. The electronic device as claimed in claim 16, wherein the main body comprises one first clamping member locating at one side of the opening, the detachable structure comprises one second clamping member for engaging with the first clamping member for preventing the detachable structure moving away from the main body.

18. The electronic device as claimed in claim 17, wherein the first clamping member comprise a first rib and a second rib connected to the first rib, the second clamping member comprises two spaced apart posts and a hook disposed on one end of one of the posts, the posts clamps the first rib for preventing the detachable structure from moving away from the main body along a first direction perpendicular to the bottom plate, the hook hooks on the second rib for preventing the detachable structure from moving away from the main body along a second direction parallel with the bottom plate.

19. The electronic device as claimed in claim 18, wherein the bottom plate defines at least one notch in an inner surface thereof adjacent to the first slot, the detachable structure comprises at least one block received in the at least one notch for preventing the detachable structure moving away from the main body along the second direction.

20. The electronic device as claimed in claim 19, wherein the detachable structure comprises a first part coplanar with the bottom plate and a second part substantially coplanar with the side plate, the second slot is defined in the first part, the at least one block projects from the first part, and the second clamping member protrudes from the second part.
